(19) United States
(12) Patent Application Publication
(10) Pub. No.: US 2026/0059880 A1
(43) Pub. Date: Feb. 26, 2026

(54) IMAGE SENSING DEVICE AND METHOD FOR MANUFACTURING THE SAME

(71) Applicant: SK hynix Inc., Icheon-si (KR)

(72) Inventor: Han Seung LEE, Icheon-si (KR)

(21) Appl. No.: 19/020,042

(22) Filed: Jan. 14, 2025

(30) Foreign Application Priority Data
Aug. 22, 2024 (KR) 10-2024-0112678

(51) Int. Cl. H10F 39/00; H10F 39/18

(52) U.S. Cl. CPC H10F 39/8057; H10F 39/014; H10F 39/024; H10F 39/182; H10F 39/8053; H10F 39/807; H10F 39/811

(57) ABSTRACT

Image sensing devices and methods for manufacturing the image sensing devices are disclosed. In an embodiment, an image sensing device may include a plurality of image sensing pixels disposed in a substrate. Each of the plurality of image sensing pixels may include a photodetector (e.g., photodiode) disposed in a substrate, an interconnect layer disposed on a first side of the substrate; a color filter disposed on a second side of the substrate opposite to the first side of the substrate; a first light absorbing area disposed in the interconnect layer; and a second light absorbing area disposed in the substrate.

This patent document claims the priority and benefits of Korean Patent Application No. 10-2024-0112678, filed on Aug. 22, 2024, which is incorporated by reference in its entirety as part of the disclosure of this patent document.

### TECHNICAL FIELD

Various embodiments of the disclosed technology relate to an image sensing device and a method for manufacturing the same, and, more particularly, to an image sensing device that includes light absorbing areas to prevent optical crosstalk between adjacent pixels and a method for manufacturing the same.

### BACKGROUND

An image sensing device is a device that captures optical images by utilizing the properties of a light sensitive semiconductor material that reacts to light. With the development of industries such as automobiles, medical, computers and communications, there is increasing demand for high-performance image sensing devices in various fields such as smartphones, digital cameras, gaming devices, the internet of Things, robots, security cameras and medical micro cameras.

Image sensing devices may be broadly categorized into charge coupled device (CCD) image sensing devices and complementary metal oxide semiconductor (CMOS) image sensing devices.

### SUMMARY

The disclosed technology can be implemented in some embodiments to provide an image sensing device and a manufacturing thereof that can prevent optical crosstalk in adjacent pixels caused by light generated during a quenching operation following an avalanche operation.

In an embodiment, an image sensing device may include: a plurality of image sensing pixels configured to convert incident light to generate electrical signals. In an embodiment, each of the plurality of image sensing pixels may include a photodetector (e.g., photodiode) disposed in a substrate; an interconnect layer disposed on a first side of the substrate; a color filter disposed on a second side of the substrate opposite to the first side of the substrate; a first light absorbing area disposed in the interconnect layer; and a second light absorbing area disposed in the substrate. In an example, the first light absorbing area extends through the interconnect layer, and the second light absorbing area extends through the substrate.

In an embodiment, the first light absorbing area may include: a first portion disposed in the interconnect layer, and a second portion disposed in the substrate.

In an embodiment, the second light absorbing area may be disposed over the first light absorbing area.

In an embodiment, the second light absorbing area may extend into the color filter. For example, an upper end of the second light absorbing area is disposed in an area of the color filter.

In an embodiment, the first light absorbing area and the second light absorbing area may be arranged continuously. For example, an upper end of the first light absorbing area is directly or indirectly connected to a lower end of the second light absorbing area.

In an embodiment, the first light absorbing area and the second light absorbing area may extend through the substrate. For example, the first light absorbing area and the second light absorbing area penetrate the substrate.

In an embodiment, the image sensing device may further include a first isolation area disposed between the first light absorbing area and the second light absorbing area.

In an embodiment, the first light absorbing area, the second light absorbing area, and the first isolation area may extend through the substrate.

In an embodiment, the image sensing device may further include a second isolation area disposed over the second light absorbing area.

In an embodiment, the second isolation area may be disposed in one area of the color filter.

In an embodiment, the first isolation area may include an insulating material.

In an embodiment, the second isolation area may include an air layer.

In an embodiment, the second light absorbing area may include a first portion disposed over the first isolation area, and a second portion extending into an area of the color filter.

In an embodiment, the first light absorbing area may include a polysilicon (Poly Si).

In an embodiment, the second light absorbing area may include a material with a high infrared ray absorption rate (e.g., a first infrared ray absorption rate that is higher than a reference infrared ray absorption rate).

In an embodiment, the second light absorbing area may include at least one of a photoglass material, a metal oxide and an organic coating material.

In an embodiment, an image sensing device includes: a semiconductor substrate; a plurality of first light absorbing areas disposed in a plurality of first area of the semiconductor substrate; a plurality of photodiodes disposed in a plurality of second areas of the semiconductor substrate such that a first portion of each of the plurality of photodiodes is disposed between two adjacent first light absorbing areas of the plurality of first light absorbing areas; and a plurality of second light absorbing areas disposed in a plurality of third areas of the semiconductor such that a second portion of each of the plurality of photodiodes is disposed between two adjacent second light absorbing areas of the plurality of second light absorbing areas.

In an embodiment, the plurality of second light absorbing areas may extends through the semiconductor substrate.

In an embodiment, the image sensing device may further include a first isolation area disposed at an end of the second light absorbing area.

In an embodiment, the second light absorbing area and the first isolation area may extend through the semiconductor substrate.

### BRIEF DESCRIPTION OF THE DRAWINGS

FIG. 1 is a block view of an image sensing device based on an embodiment.

FIG. 2 is a sectional view of a pixel array based on an embodiment.

FIG. 3 is a sectional view of a pixel array based on an embodiment.

FIG. 4 is a sectional view of a pixel array based on an embodiment.

FIG. 5 is a sectional view of a pixel array based on an embodiment.

FIGS. 6 to 12 show a method for manufacturing an image sensing device based on an embodiment.

### DETAILED DESCRIPTION

Features, and certain advantages in connection with specific implementations of the disclosed technology disclosed in this patent document are described by example embodiments with reference to the accompanying drawings.

A light detection and ranging (LiDAR) sensor with single-photon avalanche diode (SPAD) characteristics detects light in the infrared range and generates light during a quenching process after an avalanche operation. However, the light generated during the quenching process after the avalanche operation can cause optical crosstalk in adjacent pixels due to light generated during the quenching operation after the avalanche operation.

In some implementations, an image sensing device may address the optical crosstalk issues by including ae first light absorbing area that includes a poly material with a high light absorption rate and a second light absorbing area that includes a photoglass material with a high light absorption rate, thereby forming a complete shieled structure. In this way, the image sensing device may prevent optical crosstalk between adjacent pixels.

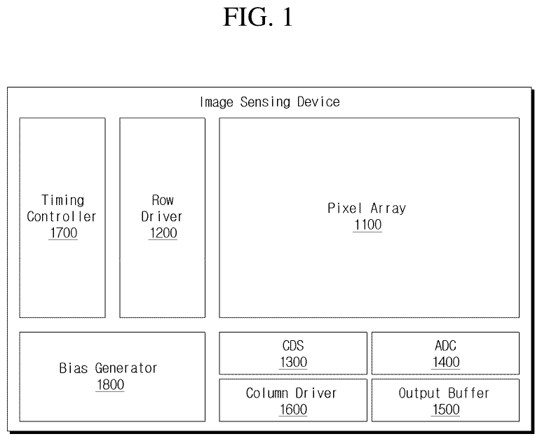

FIG. 1 is a block view of an image sensing device based on an embodiment.

Referring to FIG. 1, the image sensing device based on an embodiment may include a pixel array 1100, a low driver 1200, a correlate double sampler CDS 1300, an analog-digital converter ADC 1400, an output buffer 1500, a column driver 1600, a timing controller 1700 and a bias generator 1800. The configuration of the image sensing device illustrated in FIG. 1 is merely an example, and at least some of the components may be omitted or one or more components may be added.

The pixel array 1100 may include a plurality of pixels arranged in rows and columns. In one embodiment, the plurality of pixels may be arranged in a pixel array including rows and columns. The plurality of pixels may convert optical signals into electrical signals on a pixel-by-pixel basis or a pixel group basis.

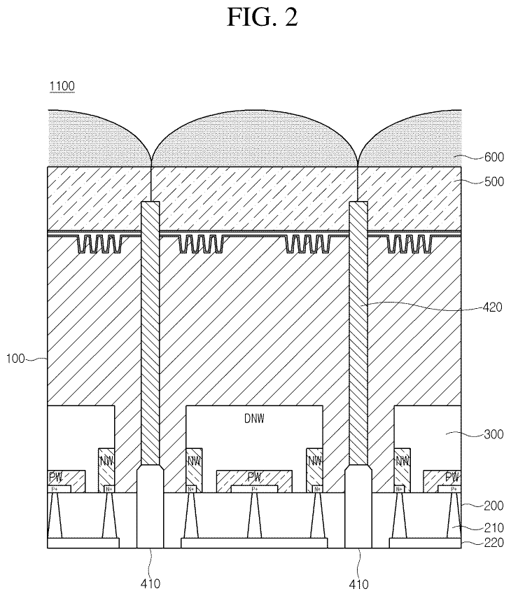

FIG. 2 is a sectional view of a pixel array based on an embodiment.

Referring to FIG. 2, an image sensing device based on an embodiment may include a pixel array 1100 that includes a plurality of pixels arranged in the pixel array 1100. Each pixel may include a portion of a substrate 100, an interconnect layer 200, a photodiode 300, a first light absorbing area 410, a second light absorbing area 420, a color filter 500 and a microlens 600.

The substrate 100 may include a semiconductor substrate. The semiconductor substrate may be in a single crystal state and may include silicon.

The substrate 100 may be a substrate thinned through a thinning process. In an implementation, the substrate 100 may be a bulk silicon substrate that has been thinned through a thinning process. In an implementation, the substrate 100 may include P-type impurities.

The interconnect layer 200 may be formed on one side or a lower portion of the substrate 100, and may include a plurality of contact areas 210 and a metal shield layer 220.

In an implementation, the contact area 210 may include a metal such as tungsten W, copper Cu, aluminum Al, or titanium Ti, a metal compound such as titanium nitride TiN, or a metal silicide such as tungsten silicide WSi or titanium silicide TiSi.

In an implementation, the contact area 210 may be used to transmit an electrical signal between different layers, e.g., vertically stacked layers.

The metal shield layer 220 may block light that is reflected from a metal line (not shown) and directed to the photodiode 300.

The photodiode 300 may be formed over the interconnect layer 200 and the substrate 200. An N-type impurity area and a P-type impurity area may be stacked in a vertical direction. The N-type impurity area and the P-type impurity area may be formed through an ion injection process.

In an implementation, the first light absorbing area 410 may be a front grid area formed in the interconnect layer 200, and may be configured to absorb or reflect light to prevent light from entering adjacent pixels.

In an implementation, one area of the first light absorbing area 410 may be formed in the interconnect layer 200 and another area of the first light absorbing area 410 may be formed in the substrate 100.

The first light absorbing area 410 may include a poly material with a high light absorption rate.

In an implementation, the first light absorbing area 410 may include polysilicon (Poly Si).

The lidar sensor having single-photon avalanche diode SPAD characteristics may detects light in the infrared range and may generate light during a quenching process after an avalanche process. In some cases, optical crosstalk may occur in adjacent pixels due to the light generated during the quenching operation after the avalanche operation. The disclosed technology can be implemented in some embodiments to address these issues by absorbing or reflecting the light generated during the quenching operating after the avalanche operation using the first light absorbing area 410 including the poly material with a high light absorption rate, optical crosstalk may be effectively suppressed in adjacent pixels.

The second light absorbing area 420 may be disposed between two adjacent photodiodes 300, and may be formed in the substrate 100.

In an implementation, the second light absorbing area 420 may be a back deep trench isolation BDTI area formed over the first light absorbing area 410 and one side of the photodiode 300, and may be configured to absorb or reflect light to prevent light from entering adjacent pixels.

In an implementation, one area of the second light absorbing area 420 may be formed over the first light absorbing are 410 and another area of the second light absorbing area 420 may be formed up to one area of the color filter 500.

In an implementation, the second light absorbing area 420 may include photoglass with a high infrared absorption rate.

In an implementation, the photoglass material may include at least one of a metal oxide (e.g., TiO2, ZrO2, In2O3, NiO) or an organic coating material (e.g., C12H25-TiO2, C12H25-TiO2-Au).

The second light absorbing area 420 may absorb or reflect infrared ray incident through the microlens 600, and may absorb or reflect light generated during the quenching operation after the avalanche operation.

In some implementations, the second light absorbing area 420, which includes a material with a high light absorption rate, such as photoglass, can absorb or reflect light, thereby preventing optical crosstalk that would have been occurred in adjacent pixels due to the light generated during the quenching operation after the avalanche operation.

In some implementations, the first light absorbing area 410, which includes a material with a high light absorption rate, such as the poly material, and the second light absorption area 420, which includes another material with a high light absorption rate, such as the photoglass can form a fully shielded structure, thereby preventing the optical crosstalk between adjacent pixels.

In an implementation, the second light absorbing area 420 may include at least one of a silicon oxide nitride film SiON, a silicon oxide film SiO, a silicon nitride film SiN, or polysilicon Poly Si.

The first light absorbing area 410 and the second light absorbing area 420 may be formed such that a combined structure of the first light absorbing area 410 and the second light absorbing area 420 penetrates the substrate 100. The first light absorbing area 410 and the second light absorbing area 420 may be formed continuously and sequentially. For example, the first light absorbing area 410 and the second light absorbing area 420 are continuously linked or seamlessly connected. Accordingly, a trench structure that penetrates or extends through the substrate and other layers can form a complete shielded structure, thereby preventing optical crosstalk between adjacent pixels.

The color filter 500 may be formed over the substrate 100, and may be configured to filter visible light from light incident through the microlens 600 and pass it through.

The microlens 600 may be formed over the color filter 500, and may be configured to collect light incident from the outside.

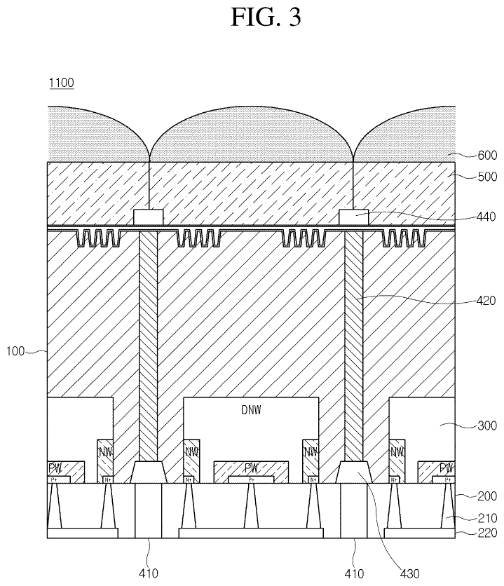

FIG. 3 is a sectional view of a pixel array based on an embodiment.

Referring to FIG. 3, an image sensing device based on an embodiment may include a pixel array 110 in which a plurality of pixels are arranged. Each pixel may include a substrate 100, an interconnect layer 200, a photodiode 300, a first light absorbing area 410, a second light absorbing area 420, a first isolation area 430, a second isolation area 440, a color filter 500 and a microlens 600.

The first isolation area 430 may be a shallow trench isolation STI area formed between the first light absorbing area 410 and the second light absorbing area 420, and may be configured to electrically isolate adjacent transistors. The first isolation area 430 may include an insulating material (e.g., oxide).

The second isolation area 440 may be a backside grid area formed over the second light absorbing area 420 and one area of the color filter 500, and may be configured to absorb or reflect light to prevent light from entering adjacent pixels.

The second isolation area 440 may include a photoglass material with a high infrared ray absorption rate, in an implementation.

In an implementation, the second isolation area 440 may be a metal grid W Grid including a metal material (e.g., titanium nitride TiN, tungsten W) or an air grid Air Grid including an air region.

In an implementation, the photoglass material may include at least one of a metal oxide (e.g., TiO2, ZrO2, In2O3, NiO) and an organic coating material (e.g., C12H25-TiO2, C12H25-TiO2-Au).

In an implementation, the second isolation area 440 may include Nio a metal material (e.g., titanium nitride TiN, tungsten W).

In some embodiments, the first light absorbing area 410 including a poly material having a high light absorption rate and the second light absorbing area 420 including a photoglass material having a high light absorption rate may absorb or reflect light generated during the quenching operation after the avalanche operation, thereby effectively preventing optical crosstalk in adjacent pixels.

The first light absorbing area 410, the second light absorbing area 420 and the first isolation area 430 may be formed such that a combined structure of the first light absorbing area 410, the second light absorbing area 420 and the first isolation area 430 penetrate the substrate 100 (and other adjacent layers).

The substrate 100, the interconnect layer 200, the photodiode 300, the first light absorbing area 410, the second light absorbing area 420, the color filter 500 and the microlens 600 are the same as the substrate 100, the interconnect layer 200, the photodiode 300, the first light absorbing area 410, the second light absorbing area 420, the color filter 500 and the microlens 600 described in the first embodiment, thereby omitting detailed description thereof.

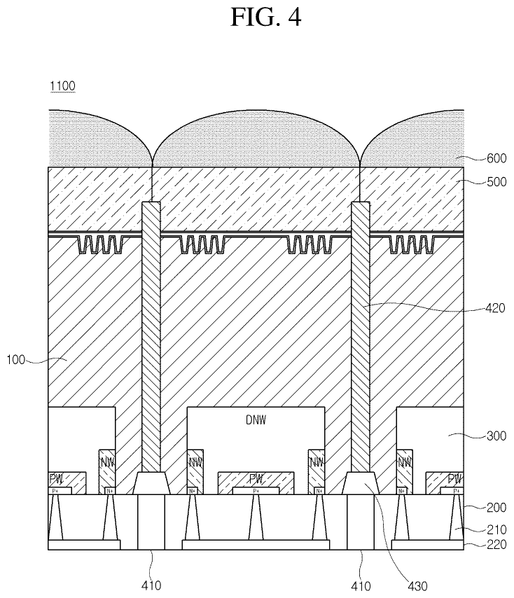

FIG. 4 is a sectional view of a pixel array based on an embodiment.

Referring to FIG. 4, an image sensing device based on an embodiment may include a pixel array 1100 in which a plurality of pixels are arranged, and each pixel may include a substrate 100, an interconnect layer 200, a photodiode 300, a first light absorbing area 410, a second light absorbing area 430, a color filter 500 and a microlens 600.

Unlike the image sensing device according to the second embodiment of FIG. 3, the image sensing device based on an embodiment has a structure in which the second light absorbing area 420 is formed up to one area of the color filter 500 without the second isolation area 440.

The first light absorbing area 410 is a front grid area formed in the interconnect layer 200, in an implementation, and may absorb or reflect light to prevent light from entering adjacent pixels.

In an implementation, the first light absorbing area 410 may be formed in the interconnect layer 200.

The first light absorbing area 410 may include a poly material with a high absorption rate.

In an implementation, the first light absorbing area 410 may include polysilicon Poly Si.

The lidar sensor having single-photon avalanche diode SPAD characteristics may receive infrared light and may generate light during the quenching process after the avalanche process. In some cases, optical crosstalk may occur in adjacent pixels due to the light generated during the quenching operation after the avalanche operation. The disclosed technology can be implemented in some embodiments to address these issues by absorbing or reflecting the light generated during the quenching operating after the avalanche operation using the first light absorbing area 410 including the poly material with a high light absorption rate.

In an implementation, the second light absorbing area 420 may be a back deep trench isolation BDTI area formed over the first light absorbing area 410 and one side of the photodiode 300, and may absorb or reflect light to prevent light from entering adjacent pixels.

One area of the second light absorbing area 420 may be formed over the first light absorbing are 410 and the other area of the second light absorbing area 420 may be formed up to one area of the color filter 500.

The second light absorbing area 420 may include photoglass with a high infrared absorption rate, in an implementation.

In an implementation, the photoglass material may include at least one of a metal oxide (e.g., TiO2, ZrO2, In2O3, NiO) and an organic coating material (e.g., C12H25-TiO2, C12H25-TiO2-Au).

The second light absorbing area 420 may absorb or reflect infrared ray incident through the microlens 600, and may absorb or reflect light generated during the quenching operation after the avalanche operation.

Through the second light absorbing area 420 including the photoglass with a high light absorption rate, the light generated during the quenching operation after the avalanche operation, thereby effectively blocking the occurrence of optical crosstalk between adjacent pixels.

Through the first light absorbing area 410 including the poly material with a high light absorption rate and the second light absorption area 420 including the photoglass with a high light absorption rate, a fully shielded structure can be formed, thereby preventing the optical crosstalk between adjacent pixels.

The second light absorbing area 420 may include, in an implementation, at least one of a silicon oxide nitride film SiON, a silicon oxide film SiO, a silicon nitride film SiN, and polysilicon Poly Si.

The first isolation area 430 may be a shallow trench isolation STI area formed between the first light absorbing area 410 and the second light absorbing area 420, and may be configured to electrically isolate adjacent transistors. The first isolation area 430 may include an insulating material (e.g., oxide).

The first light absorbing area 410, the second light absorbing area 420 and the first isolation area 430 may be formed by penetrating the substrate 100.

The substrate 100, the interconnect layer 200, the photodiode 300, the first light absorbing area 410, the second light absorbing area 420, the color filter 500 and the microlens 600 are the same as the substrate 100, the interconnect layer 200, the photodiode 300, the first light absorbing area 410, the second light absorbing area 420, the color filter 500 and the microlens 600 described in the second embodiment, thereby omitting detailed description thereof.

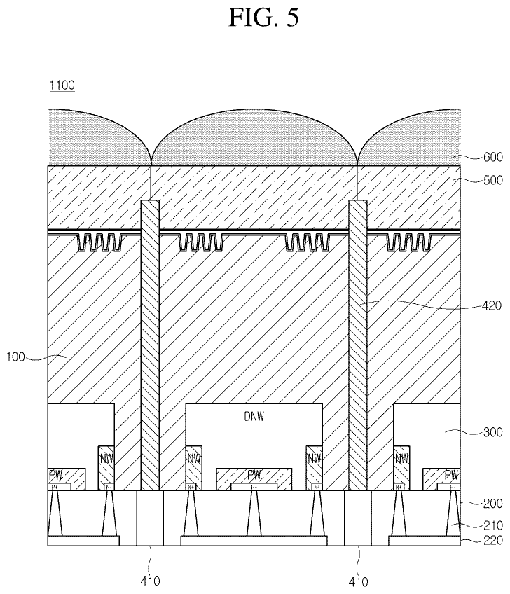

FIG. 5 is a sectional view of a pixel array based on an embodiment.

Referring to FIG. 5, an image sensing device based on an embodiment may include a pixel array 1100 in which a plurality of pixels are arranged. Each pixel may include a substrate 100, a photodiode 300, a first light absorbing area 410, a second light absorbing area 420, a color filter 500 and a microlens 600.

Unlike the image sensing device according to the first embodiment of FIG. 2, the image sensing device according to the fourth embodiment has a structure in which the first light absorbing area 410 is formed only in the interconnect layer 200.

In an implementation, the first light absorbing area 410 may be front grid area formed in the interconnect layer 200, and may absorb or reflect light to prevent light from entering adjacent pixels.

In an implementation, the first light absorbing area 410 may be formed in the interconnect layer 200.

The first light absorbing area 410 may include a poly material with high light absorption rate.

In an implementation, the first light absorbing area 410 may include polysilicon Poly Si.

The lidar sensor having single-photon avalanche diode SPAD characteristics may receive infrared light and may generate light during the quenching process after the avalanche process. Optical crosstalk may occur in adjacent pixels due to the light generated during the quenching operation after the avalanche operation. By absorbing or reflecting the light generated during the quenching operating after the avalanche operation through the first light absorbing area 410 including the poly material with high light absorption rate, optical crosstalk may be effectively suppressed from occurring in adjacent pixels.

In an implementation, the second light absorbing area 420 may be a back deep trench isolation BDTI area formed over the first light absorbing area 410 and one side of the photodiode 300, and may absorb or reflect light to prevent light from entering adjacent pixels.

In an implementation, the second light absorbing area may include a first portion disposed over the first light absorbing are 410 and a second portion extending into an area of the color filter 500.

In an implementation, the second light absorbing area 420 may include photoglass with a high infrared absorption rate.

In an implementation, the photoglass material may include at least one of a metal oxide (e.g., TiO2, ZrO2, In2O3, NiO) or an organic coating material (e.g., C12H25-TiO2, C12H25-TiO2-Au).

The second light absorbing area 420 may absorb or reflect infrared light entering through the microlens 600, and may absorb or reflect light generated during the quenching operation after the avalanche operation.

In an implementation, the second light absorbing area 420 including the photoglass with a high light absorption rate may absorb or reflect light generated during the quenching operation after the avalanche operation, thereby effectively reducing or preventing the occurrence of optical crosstalk between adjacent pixels.

In an implementation, the first light absorbing area 410 including the poly material with a high light absorption rate and the second light absorption area 420 including the photoglass with a high light absorption rate may form a fully shielded structure, thereby preventing the optical crosstalk between adjacent pixels by absorbing or reflecting light.

In an implementation, the second light absorbing area 420 may include at least one of a silicon oxide nitride film SiON, a silicon oxide film SiO, a silicon nitride film SiN, or polysilicon Poly Si.

In an implementation, the first light absorbing area 410 and the second light absorbing area 420 may penetrate the substrate 100. The first light absorbing area 410 and the second light absorbing area 420 may be formed continuously and sequentially. For example, the first light absorbing area 410 and the second light absorbing area 420 are continuously linked or seamlessly connected. Accordingly, a trench structure that penetrates or extends through the substrate and other layers can form a complete shielded structure, thereby preventing optical crosstalk between adjacent pixels.

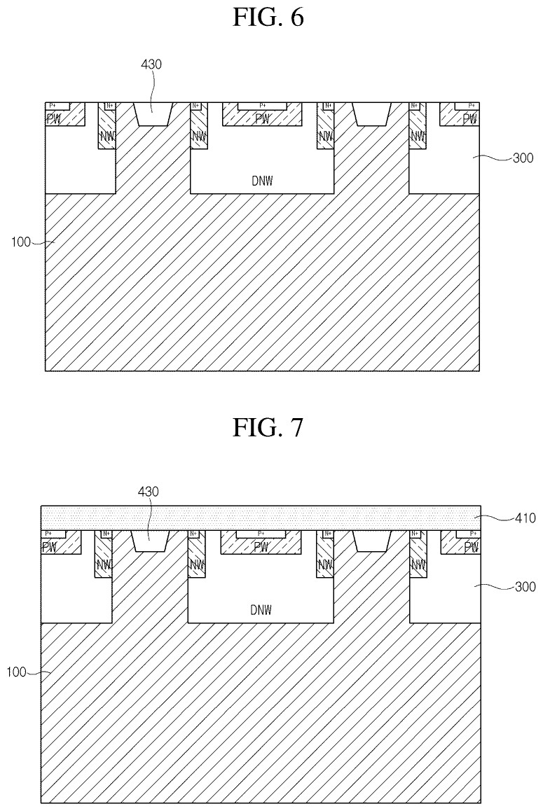

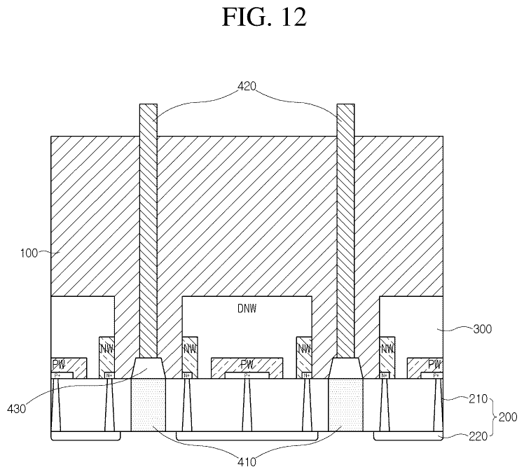

The substrate 100, the interconnect layer 200, the photodiode 300, the first light absorbing area 410, the second light absorbing area 420, the color filter 500 and the microlens 600 are the same as the substrate 100, the interconnect layer 200, the photodiode 300, the first light absorbing area 410, the second light absorbing area 420, the color filter 500 and the microlens 600 described in the first embodiment, thereby omitting detailed description thereof FIGS. 6 to 12 are views to describe a method for manufacturing an image sensing device based on an embodiment.

Referring to FIGS. 6 to 8, a method for manufacturing an image sensing device based on an embodiment may include forming a substrate 100; forming a plurality of photodetectors (e.g., photodiodes) 300; forming a plurality of first isolation areas 430 between adjacent photodiodes on a front side of the substrate 100 through a photo process, an etching process, an ashing process and an insulating material gap-filling process; and forming a first light absorbing area 410 on one side of the first isolation area 430 through a poly material disposition process.

Referring to FIG. 7, the first isolation area 430 may be formed between adjacent photodiodes on a front side of the substrate 100 through the photo process, the etching process, the ashing process and the insulating material gap-filling process, which are formed.

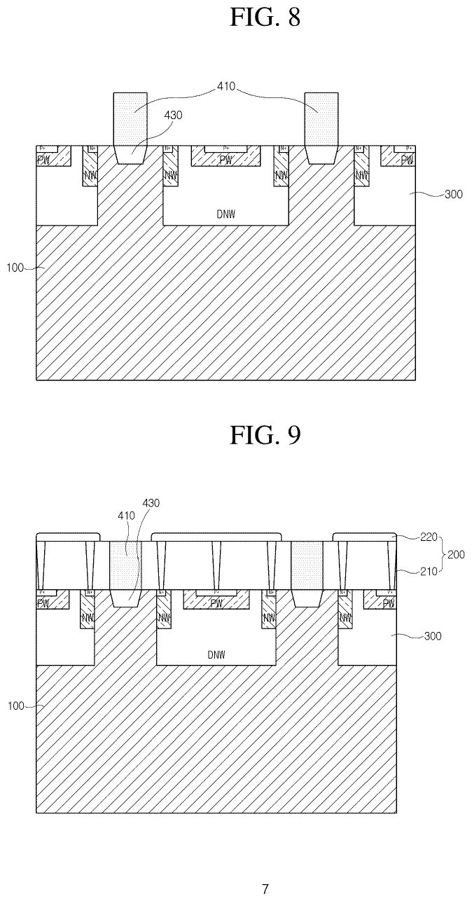

Referring to FIG. 8, through the etching process after the poly material disposition, the first light absorbing area 410 may be formed to be in contact with one side of the first isolation area 430.

The first isolation area 430 may include an insulating material (e.g., oxide).

The first light absorbing area 410 may include a poly material with a high absorption rate.

In an implementation, the first light absorbing area 410 may include a polysilicon (Poly Si).

Referring to FIG. 9, after forming the first light absorbing area 410, an interconnect layer 200 including a contact area 210 and a metal shield layer 220 may be formed in one side of the first light absorbing area 410.

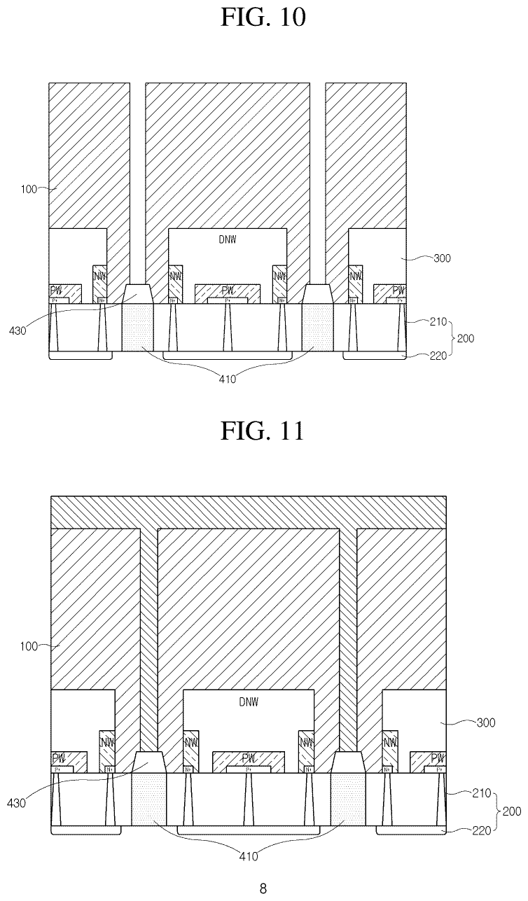

Referring to FIGS. 10 to 12, after forming the interconnect layer 200, a second light absorbing area 420 may be formed on the other side of the first isolation area 430 through a photo process, an etching process, an ashing process and a photoglass material gap-filling process, which are performed on a backside of the substrate.

In an implementation, the second light absorbing area 420 may include a phogoglass material with a high infrared ray absorption rate.

In an implementation, the photoglass material may include at least one of a metal oxide (e.g., TiO2, ZrO2, In2O3, NiO) or an organic coating material (e.g., C12H25-TiO2, C12H25-TiO2-Au).

In an implementation, the second light absorbing area 420 may include at least one of a silicon oxide nitride film SiON, a silicon oxide film SiO, a silicon nitride film SiN, or polysilicon Poly Si.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device comprising:
a plurality of image sensing pixels,
wherein each of the plurality of image sensing pixels comprises,
a photodiode disposed in a substrate;
an interconnect layer disposed on a first side of the substrate;
a color filter disposed on a second side of the substrate opposite to the first side of the substrate;
a first light absorbing area disposed in the interconnect layer; and
a second light absorbing area disposed in the substrate.

2. The image sensing device of claim 1, wherein the first light absorbing area includes: a first portion that is disposed in the interconnect layer; and a second portion that is disposed in the substrate.

3. The image sensing device of claim 2, wherein the second light absorbing area is disposed over the first light absorbing area.

4. The image sensing device of claim 3, wherein one area of the second light absorbing area is disposed in one area of the color filter.

5. The image sensing device of claim 1, wherein an upper end of the first light absorbing area is directly or indirectly connected to a lower end of the second light absorbing area.

6. The image sensing device of claim 5, wherein the first light absorbing area and the second light absorbing area extend through the substrate.

7. The image sensing device of claim 1, further comprising:
a first isolation area disposed between the first light absorbing area and the second light absorbing area.

8. The image sensing device of claim 7, wherein the first light absorbing area, the second light absorbing area, and the first isolation area extend through the substrate.

9. The image sensing device of claim 7, further comprising:
a second isolation area disposed over the second light absorbing area.

10. The image sensing device of claim 9, wherein the second isolation area is disposed in an area of the color filter.

11. The image sensing device of claim 7, wherein the first isolation area includes an insulating material.

12. The image sensing device of claim 9, wherein the second isolation area includes an air layer.

13. The image sensing device of claim 7, wherein the second light absorbing area includes:
a first portion disposed over the first isolation area, and
a second portion extending into an area of the color filter.

14. The image sensing device of claim 1, wherein the first light absorbing area includes a polysilicon.

15. The image sensing device of claim 1, wherein the second light absorbing area includes a material with a first infrared ray absorption rate that is higher than a reference infrared ray absorption rate.

16. The image sensing device of claim 1, wherein the second light absorbing area comprises at least one of a photoglass material, a metal oxide and an organic coating material.

17. An image sensing device comprising:
a semiconductor substrate;
a first light absorbing area disposed in the semiconductor substrate;
a plurality of photodiodes disposed in the semiconductor substrate; and
a second light absorbing area substrate that separates each of the plurality of photodiodes and is disposed in disposed in the semiconductor substrate.

18. The image sensing device of claim 17, wherein the second light absorbing area extends through the semiconductor substrate.

19. The image sensing device of claim 17, further comprising:
a first isolation area disposed at an end of the second light absorbing area.

20. The image sensing device of claim 19, wherein the second light absorbing area and the first isolation area extend through the semiconductor substrate.
